(19) United States
(12) Patent Application Publication
(10) Pub. No.: US 2026/0255511 A1
(43) Pub. Date: Aug. 27, 2026

(54) VEHICLE DEVICE WITH SPECIFIC CABLE CONNECTION BETWEEN A FAN AND A HOUSING THAT IS SEPARATE THERETO AND COMPRISES A PRINTED CIRCUIT BOARD

(71) Applicant: CONNAUGHT ELECTRONICS Ltd., Tuam, County Galway (IE)

(72) Inventor: Justyna Bogiel, Tuam, Galway (IE)

(73) Assignee: CONNAUGHT ELECTRONICS Ltd., Tuam, County Galway (IE)

(21) Appl. No.: 19/107,030

(22) PCT Filed: Aug. 30, 2023
(86) PCT No.: PCT/EP2023/073755

§ 371 Date: Feb. 27, 2025

(30) Foreign Application Priority Data
Aug. 30, 2022 (DE) 10 2022 121 908.9

(51) Int. Cl. H05K 5/02; H05K 5/06; H05K 7/20

(52) U.S. Cl. CPC H05K 5/0247; H05K 5/069; H05K 7/20863

(57) ABSTRACT

A vehicle device includes a housing, in which at least one printed circuit board is arranged, and a fan, which is arranged outside the housing, and with an electric cable, which is laid through a cable opening in the housing and extends outside and inside the housing. The cable is connected to electric connection of the fan and which is connected to the printed circuit board. The cable outside the housing is arranged on a guiding element arranged adjacent to the cable opening, and is laid bent by the guiding element of the vehicle device towards the cable opening. The cable opening is arranged at a height position viewed in the height direction of the vehicle device, which is higher than a lowest point of the guiding element contacted by the cable.

One aspect of the invention relates to a vehicle device comprising a housing, in which at least one printed circuit board is arranged.

Vehicle devices are known in manifold designs. They may be a variety of component constellations, in which wire-bound electric connections are to be established. Especially when the vehicle device also comprises a housing in which an interconnect device or a printed circuit board, respectively, is arranged and for this purpose a wire-bound connection to an external component part of the vehicle device is to be effected, various aspects arise.

It is an objective of the present invention to provide a vehicle device, in which an electric connection between a printed circuit board and a further component of the vehicle device is technically improved in a wire-bound manner.

This objective is solved by a vehicle device comprising the features according to claim 1.

One aspect of the invention relates to a vehicle device comprising a housing. The vehicle device moreover comprises at least one printed circuit board arranged in the housing. Moreover the vehicle device comprises a fan. This fan is arranged outside the housing. The vehicle device moreover comprises at least one electric cable, which is laid through a cable opening in the housing and extends both outside and inside the housing. The cable is connected to an electric connection of the fan. The cable is moreover also connected to the printed circuit board in the housing. The cable outside the housing is arranged on a cable guiding element of the vehicle device. The guiding element is arranged adjacent to the cable opening. The cable is arranged bent by the guiding element towards the cable opening. The cable opening is arranged at a height position viewed in the height direction of the vehicle device, which is higher than a lowest point of the guiding element. At this lowest point of the guiding element the cable contacts the guiding element, in particular directly. This means consequently that as lowest point of the guiding element is regarded that one at which the cable opening also contacts, in particular directly contacts, the guiding element.

By such a vehicle device it is facilitated that an electric, wire-bound connection between the printed circuit board in the housing and a fan of the vehicle device that is external to the housing is formed. Since in such constellations it is required that a cable opening in the housing is configured to be able to lay the cable from the inside of the housing to the outside towards the fan, influences that are to be observed there may occur. This may for instance be a correspondingly stable laying of the cable in the region of the cable opening. In particular here also an exactly positioned laying of the cable should be facilitated. Undesired movements or tolerances of the cable should thereby be avoided. Moreover the cable should preferably also be arranged as tight as possible in the corresponding opening in order to avoid an undesired shifting. In particular it is also envisaged that an entering of liquid into the housing, in particular via the cable opening, can be avoided in an improved manner.

This is fulfilled in many respects in the suggested vehicle device. This is because by the guiding element arranged adjacent to the cable opening the cable is guided already in a highly directed and guided way to the cable opening. Thus, the cable may already contact the guiding element secured in position, in particular also in a tight manner. Especially by the guiding element the cable thus is also diverted in a highly targeted and highly defined manner towards the cable opening. By moreover also the guiding of the cable by the guiding element outside the cable opening being such that it is positioned at a point lower than in the region of the cable opening itself, by this very defined established and desired height offset also a prevention of media entering via the cable into the cable opening can be better avoided. This is because it is true that in this way in particular for instance by this exact position definition also liquid can run outside the housing along the cable. Due to this height offset, however, it is then not possible that the water rising from the lowest point reaches the cable opening again and then arrives via the cable opening into the interior of the housing. Moreover, by this height offset it is also very advantageously facilitated that the cable from this lowest point to the cable opening is equally arranged in exact position and tight. Also thereby undesired movement tolerances of the cable can be avoided in exactly this region.

In an embodiment the cable starting from the lowest point, at which it is arranged contacting the guiding element, is laid upwards towards the cable opening. The advantages in this regard are already named above. In an embodiment the cable opening is bounded by an elevation rising at least on one side. This rising elevation thus is also guided from the bottom to the top. Thus, in an embodiment the cable is guided coming from the guiding element carried by this rising elevation and in a targeted way to the cable opening. Thereby, too, the higher positioning of the cable directly at the cable opening or its entrance is achieved.

It may be envisaged that the elevation is a hump-shaped elevation. In particular on the external surface of the housing here this elevation is rising, then reaches a maximum, and is sloping down again towards the interior of the housing. Thereby the hump shape is formed. By such a construction of the elevation by the maximum a defined highest positioned point at the cable opening is configured. Exactly at the cable opening in an advantageous embodiment there is this hump tip or the maximum of this hump-shaped elevation, respectively. Thus, exactly in the region of the cable opening the cable at this peak point can be particularly advantageously guided or laid, respectively. A very locally defined bearing area of the cable in this exact height position in the cable opening is thereby achieved. Thus, also the inner width of the cable opening viewed in the height direction can be minimized and thus quasi a gap-like opening be configured. Also thereby, on the one hand, advantageously a relatively accurately fit passing of the cable through the cable opening is facilitated and still this higher position state of the cable at the cable opening in comparison with the lowest point on the guiding element supported. Not least, by this arrangement of the maximum of the hump-shaped elevation exactly in the region of the cable opening or at the entrance of the cable opening advantageously a tight laying of the cable into the interior of the housing is supported.

In an embodiment the elevation comprises an elevation plateau. This elevation plateau is arranged at a height position which is higher than the lowest point of the guiding element on which the guiding element is arranged directly contacting the guiding element. This elevation plateau may be the above-named maximum of the hump-shaped elevation.

In an embodiment by the elevation plateau a bottleneck of the cable opening viewed in the height direction is formed. Also for this purpose the achievable advantages are already named above. Such smallest possible inner width of the cable opening, in particular in the height direction, here, too, facilitates a space-saving concept. Moreover, a compact passing of the cable through the cable opening is facilitated so that as little as possible clearance between the cable and the cable opening is formed.

In an embodiment this bottleneck viewed in the height direction of the vehicle device is arranged to be positioned higher than the lowest point of the guiding element contacted by the cable.

In an embodiment the elevation comprises an external wall sloping down towards the outside. This sloping down towards the outside is in particular to be understood in such a way that this external wall starting from the entrance of the cable opening is sloping down towards the guiding element. In particular, here an oblique sloping down can be configured. Thus, very advantageously by an external wall oriented in such way also a further guiding of the cable separately from the guiding element and towards the cable opening is achieved. Further, by such an external wall sloping down towards the outside also an advantage with regard to the avoidance of media entering the cable opening is supported. In particular this external wall viewed in the height direction sloping down towards the outside at least in portions is arranged to overlap with the guiding element. Thus, to a certain extent a labyrinth path between the guiding element and this external wall sloping down towards the outside is formed in front of the cable. Also thereby an advantageous laying path for the cable is formed, in particular with regard to the advantages already named above.

In an embodiment the external wall sloping down towards the outside is curved, in particular concavely curved, at least in portions. This is a further advantageous embodiment in order to achieve a secure laying of the cable coming from the guiding element towards the cable opening. Thus, the cable can be guided very advantageously to the cable opening. Not least, by such a concave curvature also the avoidance of media, such as dust or liquid, to the cable opening is supported in an enhanced way.

In an embodiment the external wall is arranged adjacent to the guiding element so that between a lower outer side of the guiding element and the external wall a duct for the cable is formed. Also thereby the laying of the cable and the targeted guiding towards the cable opening is improved.

In an embodiment the shape design of the lower outer side of the guiding element is adjusted to the shape design of the external wall. Also thereby the laying of the cable in a defined guided way, in particular also in a tightened state, can be achieved in an improved way.

In an embodiment on an external rim edge of the external wall a downward angled bar is formed. The external rim edge is in particular that one facing away from the cable opening. The external rim edge in the height direction is that one which is in particular the lowest point of the external wall. The angled bar integrally formed therewith facilitates in further very advantageous way the avoidance of media entering towards the cable opening. Moreover, the external wall is stabilized by such angled bar. In particular the bar then is also a stiffening bar.

In an embodiment the bar is configured as drip-off edge for liquid and/or as splash protection element for liquid towards the cable opening. This also means that by this bar liquid, which may for instance drip off the cable, such as for instance condensate, is drained downward via this bar and there can drip off and it is avoided in an improved way that this liquid might reach the cable opening. Also when splashing water from the outside should splash against the vehicle device in the region of the guiding element, by this bar a protective shield can be created so that also splashing water in this regard cannot reach via the external wall, as it has been named above, the cable opening.

In an embodiment the guiding element comprises a cylinder segment, at which the cable is laid bent and directly arranged thereon. The guiding element in its design as cylinder segment may for instance be configured as semi-cylindrical cylinder segment. Thus, a corner-free contour may be created, on which the cable is guided directly contacting and correspondingly bent. A very continuous change in the direction of the cable is thereby facilitated without undesired bends in the cable occurring. By such a form the cable can also be diverted in a targeted way towards the cable opening.

In an embodiment the guiding element in each case comprises a guiding wall arranged to extend from the cylinder segment so that the cylinder segment viewed in axial direction is bounded by the guiding walls. In particular then by these guiding walls and the cylinder segment positioned in between a guiding element in the form of a cable drum is formed. Thus, on the one hand, the cable contacts the external wall of the cylinder segment. On the other hand, by the guiding walls formed on the end surfaces also a prevention for the cable against shifting on the cylinder segment is achieved.

In the radial direction of the cylinder segment these guiding walls are formed to project beyond the cylinder segment.

In an embodiment a fan housing of the fan is arranged on the external surface on the housing of the vehicle device, in which the printed circuit board is arranged. The fan housing in this connection may be arranged directly on the housing on the external surface. It may for instance be screwed together with it. Possible are also plug-in connections or snap-in connections. It is also possible that the fan housing is integrally formed with the housing in which the printed circuit board is arranged. The printed circuit board also in such embodiment is separated from a fan wheel of the fan, in particular by a housing wall that is separating in this regard.

The fan housing in an embodiment equally preferably comprises a cable opening through which the cable then also is guided into the interior of the fan housing to be able to be connected there with the electric connection.

In an embodiment the guiding element comprises at least one loss prevention element. The loss prevention element in particular serves for keeping the cable on the guiding element. In particular by the loss prevention element a loss prevention pin is formed. Same may preferably be arranged on an inner surface of a guiding wall facing the opposite other guiding wall. This loss protection pin thus extends, in particular cantilevering, from an inner surface of a guiding wall towards the other guiding wall. In particular, thus, a radial slipping out of the cable from the guiding element is avoided.

Embodiments of the invention are explained in the following in more detail by reference to the drawings. These show in:

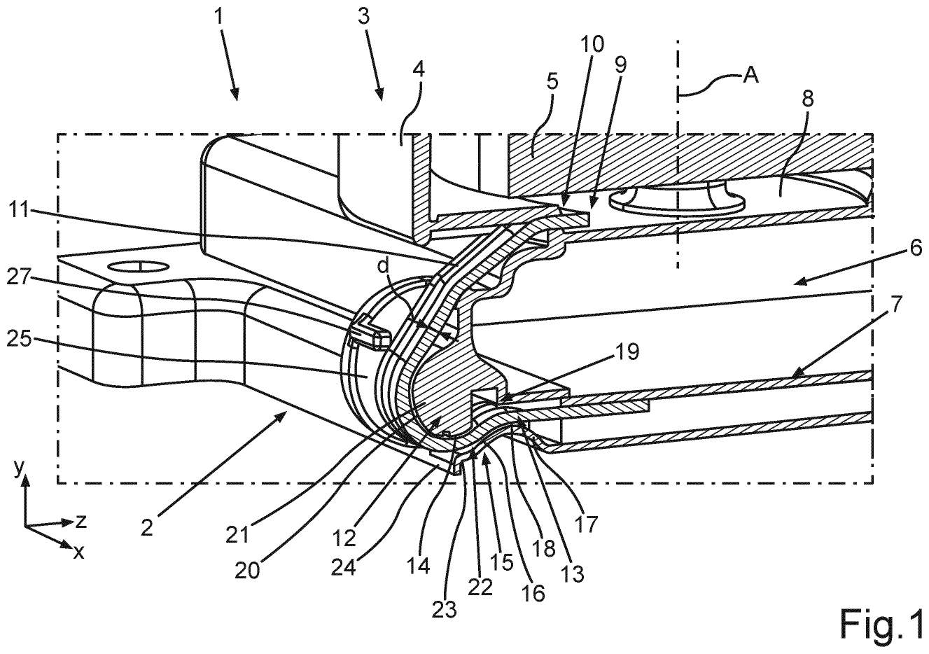

FIG. 1 a perspective sectional view through an embodiment of a vehicle device according to the invention, wherein the vehicle device is partly shown; and

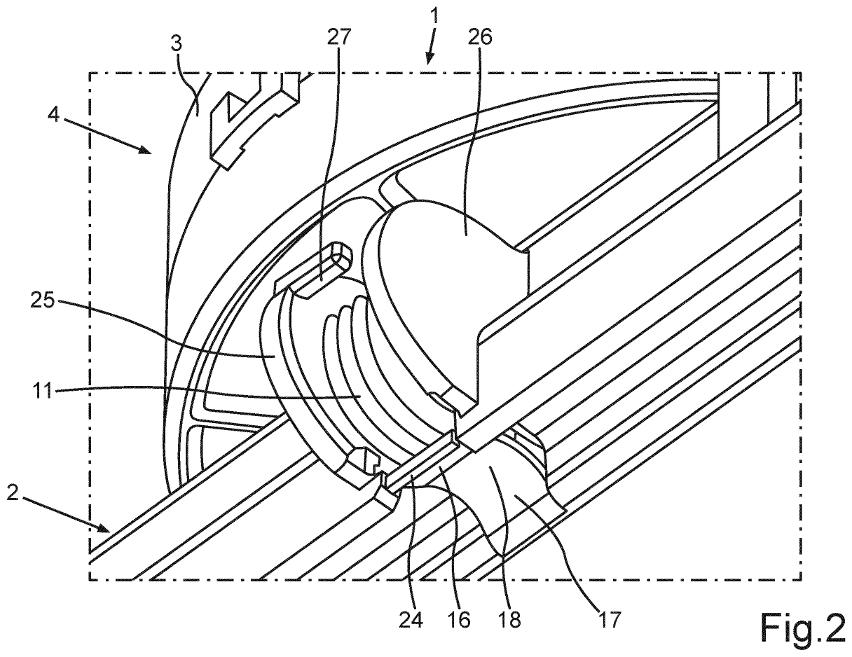

FIG. 2 a representation of a subportion in FIG. 1 is shown in a perspective view obliquely from below.

In the figures identical and functionally identical elements are equipped with the same reference signs.

In FIG. 1 a vehicle device 1 is shown. The vehicle device 1 may also be referred to as vehicle apparatus or vehicle unit. The vehicle device 1 is installed in a vehicle, such as for instance a motor vehicle. The vehicle device 1 is therefore intentionally conceived for employment in a vehicle, in particular a motor vehicle.

The vehicle device 1 comprises a housing 2. The housing 2 in an embodiment is a circumferentially closed, in particular completely closed housing. It may be made of metal. Moreover the vehicle device 1 comprises a fan 3. The fan 3 comprises a fan housing 4. In the fan housing 4 at least one fan wheel 5 is arranged, which is mounted to be rotatable about an axis A. The fan housing 4 in the embodiment is arranged outside the housing 2. It may be a fan housing 4 that is separate from the housing 2.

The fan housing 4 may be connected with the housing 2 for instance by a screw connection and/or a plug-in connection and/or by a snap-in connection. It is also possible that the housing 2 and the fan housing 4 are integrally formed. In such a common housing then a first chamber is formed, in which the fan wheel 5 is arranged. In a second chamber that is different and separate therefrom further components are arranged.

In the housing 2 a component arrangement 6 is arranged. In the housing 2 in particular also at least one printed circuit board 7 is arranged. The printed circuit board 7 thus is separated from the fan 3. In particular the printed circuit board 7 is separated by a wall 8 from the fan wheel 5. The wall 8 may be a housing wall of the housing 2. It may also be a housing wall of the fan housing 4. It is possible in a different embodiment, in which the housing 2 and the fan housing 4 are configured to be integrally formed, that it is an interior partition wall.

The fan 4 comprises an electric connection 9. This electric connection 9 is arranged in particular in the interior of the fan housing 4. The fan housing 4 comprises a cable opening 10. Through this cable opening 10 a cable 11 of the vehicle device 1 is guided. Thus, the cable 11 is laid both inside the fan housing 4 as well as outside the fan housing 4. The cable 11 establishes a wire-bound connection between the fan 3 and the printed circuit board 7. Therefore, the cable 11 is also guided into the interior of the housing 2. In the embodiment the vehicle device 1 comprises a guiding element 12. It may be referred to as cable guiding element. The guiding element 12 is component of the housing 2. The guiding element 12 may be integrally formed with the housing 2. The guiding element 12 is arranged adjacent to a cable opening 13 in the housing 2. The cable opening 13 represents a passage, through which the cable 11 is guided or laid, respectively, from outside the housing 2 into the interior of the housing 2. In the height direction (y direction) of the vehicle device 1 this cable opening 13 is arranged to be positioned higher than a lowest point 14 of the guiding element 12 contacted also by the cable 11. At this lowest point 14 in the embodiment the cable 11 is arranged in direct contact. Thus, also the cable 11 is arranged outside the housing 2 in portions lower positioned than it is arranged in the cable opening 13. Such a height offset between the lowest point 14 and the cable opening 13 amounts in an embodiment to at least the thickness d of the cable.

As can be recognized, the cable 11 is laid from this lowest point 14 upward towards the cable opening 13. In particular it is laid in this regard with an S-shaped section. This means that the S-shape is predetermined by the contour of the guiding element 12 and additional components.

The cable opening 13 is bounded by at least one elevation 15 rising at least on one side towards the cable opening 13. In particular this elevation 15 is configured to be hump-shaped. This means that the elevation 15 comprises an external wall 16 which starting from the cable opening 13 is sloping down towards the outside. The external wall 16 therein is the one that is guided starting from the cable opening 13 outward and downward. In particular this external wall 16, which is sloping down towards the outside, is concavely curved at least in portions. In the embodiment by the hump shape of the elevation 15 also an internal wall 17 is formed. The internal wall 17 starting from an elevation plateau 18, which viewed in the height direction represents the maximum of the elevation, is sloping down. In particular the walls 15 and 17 at least in portions represent housing walls of the housing 2.

As can be recognized, the elevation 15, in particular the elevation plateau 18, is formed on an entrance 19 of the cable opening 13. Thereby the cable opening 18 is formed at its entrance 19 with a corresponding bottleneck.

As can moreover be recognized, the external wall 16 is arranged spaced apart from the guiding element 12. In particular it is arranged spaced apart from a contact surface 20 of a semi-cylindrical cylinder segment 21 of the guiding element 12. By this adjacent arrangement between the cylinder segment 21 and the external wall 16 also a specifically shaped guiding duct 22 for the cable 11 is formed. In particular thus this S-shaped region of the cable 11 can be formed and the cable 11 can be laid in a defined way from the guiding element 12 towards the cable opening 13 upward.

As, moreover, can also be recognized in FIG. 1, the external wall 16 comprises an external rim edge 23. This external rim edge 23 faces away from the cable opening 13. The external rim edge 23 in the embodiment viewed in the height direction also represents the lowest point of the external wall 16. Integrally molded on this external rim edge 23, in particular by a bending, a bar 24 angled in this regard is integrally molded on. The angled bar 24 projects downward in cantilevering manner. In particular this bar 24 is a drip-off edge for liquid and/or a splash protection element for liquid. Thus, it is avoided that for instance splashing water may reach the cable opening 13 from outside the housing 2. Also liquid, which for instance runs via the cable 11 downward, can drip off via this bar 24 and thus does not reach the cable opening 13 via the external wall 16.

As can be seen in FIG. 1, the guiding element 12, in particular the cylinder segment 21, is formed semi-cylindrically.

Moreover, the guiding element in an embodiment comprises two guiding walls 25 and 26. These are molded opposite each other on the cylinder segment 21, in particular the semi-cylindrical cylinder segment 21. They extend in radial direction of the cylinder geometry further outward than the cylinder segment 21, in particular the contact surface 20. Thus, the guiding element 12 is configured in the form of a cable drum.

In an embodiment it may be envisaged that the guiding element 12 comprises a loss prevention element 27. This may be a loss prevention pin, as it is shown in FIG. 1. In the embodiment this loss prevention element 27 starting from a guiding wall 25 extends towards the other guiding wall 26. A radial sliding off of the cable 11 from the cylinder segment 21 is thereby prevented.

In FIG. 2 a representation of a subportion from FIG. 1 is shown, in which with a perspective from below the cable 11 on the guiding element 12 is shown and also the bar 24 can be recognized.

1. A vehicle device comprising:
a housing, in which at least one printed circuit board is arranged;
a fan, which is arranged outside the housing; and
an electric cable, which is laid through a cable opening in the housing and extends outside and inside the housing,
wherein the electric cable is connected to an electric connection of the fan and which is connected to the printed circuit board,
wherein the electric cable outside the housing is arranged on a guiding element arranged adjacent to the cable opening, and is laid bent by the guiding element of the vehicle device towards the cable opening,
wherein the cable opening is arranged at a height position viewed in a height direction of the vehicle device, which is higher than a lowest point of the guiding element contacted by the cable.

2. The vehicle device according to claim 1, wherein the cable starting from the lowest point of the guiding element is laid upwards to the cable opening.

3. The vehicle device according to claim 1, or wherein the cable opening is bounded by an elevation at least rising from the cable opening to the outside.

4. The vehicle device according to claim 3,
wherein the elevation comprises an elevation plateau,
wherein at least the elevation plateau is arranged at a height position, which is higher than the lowest point of the guiding element.

5. The vehicle device according to claim 4, wherein by the elevation plateau a bottleneck of the cable opening viewed in the height direction is formed at an entrance of the cable opening.

6. The vehicle device according to claim 5, wherein the bottleneck viewed in the height direction is arranged to be positioned higher than the lowest point of the guiding element.

7. The vehicle device according to claim 3, wherein the elevation comprises an external wall sloping down towards the outside.

8. The vehicle device according to claim 7, wherein the external wall that is sloping down at least in portions is curved in concave manner.

9. The vehicle device according to claim wherein the external wall is arranged adjacent to the guiding element so that between a bottom section of a contact surface of the guiding element and the external wall a duct for the cable is formed.

10. The vehicle device according to claim 9, wherein a shape design of the contact surface is adjusted to the shape design of the external wall.

11. The vehicle device according to claim 3, wherein at an external rim edge of an external wall a downward angled bar is formed.

12. The vehicle device according to claim 11, wherein the bar is configured as drip-off edge for liquid and/or as splash protection element for liquid towards the cable opening.

13. The vehicle device according to claim 1, wherein the guiding element comprises a cylinder segment, at which the cable is arranged to be laid in a bent manner.

14. The vehicle device according to claim 13,
wherein the guiding element extending from the cylinder segment in each case comprises a guiding wall, so that the cylinder segment in its axial direction is bounded on both sides by the guiding walls,
wherein the guiding element comprising the cylinder segment and the guiding walls, is configured in a form of a cable drum.

15. The vehicle device according to claim 1, wherein a fan housing of the fan is arranged externally on the housing.
